(19) United States
(12) Patent Application Publication
(10) Pub. No.: US 2010/0301495 A1
(43) Pub. Date: Dec. 2, 2010

(54) SEMICONDUCTOR DEVICE AND METHOD FOR MANUFACTURING SAME

(75) Inventor: Shinichi CHIKAKI, Ibaraki (JP)

Correspondence Address: YOUNG & THOMPSON, 209 Madison Street, Suite 500, Alexandria, VA, 22314, US

(73) Assignee: NEC ELECTRONICS CORPORATION, Kawasaki-shi (JP)

(21) Appl. No.: 12/786,871

(22) Filed: May 25, 2010

(30) Foreign Application Priority Data
May 27, 2009 (JP) 2009-127600

(51) Int. Cl. H01L 23/48; H01L 21/768

(52) U.S. Cl. 257/774; 438/666; 257/E21.585; 257/E23.011

(57) ABSTRACT

Provided is the method for manufacturing the semiconductor device including: providing a film (organic silicon polymer film) containing a silane compound and a porogen on a substrate; providing a hole (interconnect trench) in the organic silicon polymer film using a selective etching process and providing a metallic film (barrier film and copper interconnect) in the inside of the interconnect trench; and conducting a radiation with ultraviolet over the organic silicon polymer film within an atmosphere of a reducing gas while the film is heated at a temperature of not lower than a boiling point or a decomposition temperature of the porogen to obtain a microporous film.

This application is based on Japanese patent application NO. 2009-127,600, the content of which is incorporated hereinto by reference.

### BACKGROUND

1. Technical Field

The present invention relates to a semiconductor device and method for manufacturing thereof.

2. Background Art

In a semiconductor device, a technology for forming pores in an insulating film is known as a technology for forming an insulating film having a lower dielectric constant.

United States Patent Application Publication No. 2007/0161230-A1 of Chen et al. discloses a method for manufacturing a semiconductor device, which includes a low dielectric constant interlayer insulating film. According to Chen et al., a formation of a damascene interconnect is conducted after the insulating film containing a pore generating material dispersed therein is formed, and then pores are produced by exposing to a radiation with a ultraviolet of a first wave length to form an insulating film having a porous structure, and subsequently, an exposure with a ultraviolet of a second wave length, which is shorter than the first wave length, is conducted to form an insulating film having cross-linking structure. Then, an annealing process is conducted within a carbon-containing gas atmosphere to provide an increased carbon content in the insulating film.

In addition, R. Caluwaerts et al., entitled “POST PATTERNING MESO POROSITY CREATION: A POTENTIAL SOLUTION FOR PORE SEALING,” Proceedings of IITC 2003 pp. 242-244, discloses that, after a pattern processing of an insulating film is carried out, pores are produced in a film to form a low dielectric constant insulating film. According to Caluwaerts et al., SiLK (v7) (trademark) resin is applied over the substrate, and the substrate is heated at a temperature of 150 degree centigrade (degree C.) and at a temperature of 400 degrees C. to form a film without a pore. Subsequently, SiLK (v7) (trademark) resin is patterned, and then the substrate is heated at a temperature of 430 degrees C. to generate pores.

When the film containing the pore generating material dispersed therein is exposed to an energy such as an ultraviolet radiation or a heat to generate pores, the film is shrunk while pores are generated in such film.

According to Chen et al., the damascene interconnect is formed in the interlayer insulating film containing the pore generating material dispersed therein, and then pores are generated in such interlayer insulating film.

A shrinking force is caused in the interlayer insulating film, and thus an adhesion of the interlayer insulating film and the interconnect creates a tensile stress acting in the interlayer insulating film.

The present inventor has recognized as follows. The conventional technologies disclosed in the above-described related art documents have the following problems. As described above, the a tensile stress acting in the interlayer insulating film due to the adhesion of the interlayer insulating film and the interconnect generates a crack in the interlayer insulating film, and thus, it is difficult to obtain a semiconductor device with high reliability. While the above description is made in relation with the combination of the interlayer insulating film and the interconnect, similar problems may be arisen in relation with the combination of the interlayer insulating film and the via and/or the contact.

### SUMMARY

According to one aspect of the present invention, there is provided a method for manufacturing a semiconductor device, including: providing a film containing a silane compound and a porogen over a substrate; forming a hole in the film using a selective etching process and forming a metallic film in the inside of the hole: and conducting a radiation with ultraviolet over the film within an atmosphere of a reducing gas while the film is heated at a temperature to obtain a microporous film, the temperature being not lower than a boiling point or a decomposition temperature of the porogen.

According to another aspect of the present invention, there is provided a semiconductor device, including: a substrate; a microporous film provided over the substrate; a hole provided in the microporous film; and a metallic film provided in the inside of the hole, wherein a stress in the microporous film in vicinity of the metallic film is a compressive stress.

In the microporous film, which is obtained by conducting a radiation with ultraviolet over the film within an atmosphere of a reducing gas while the film is heated at a temperature of not lower than a boiling point or a decomposition temperature of the porogen, a stress in the microporous film in vicinity of the metallic film is a compressive stress. Since no tensile stress is generated as described above, a breakaway of a film due to a defect caused in the manufacturing process can be prevented.

According to the present invention, a structure that provides a semiconductor device with improved reliability and a method for manufacturing thereof are provided.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a flow chart, showing an example of a procedure for manufacturing a semiconductor device in an embodiment according to the present invention;

FIGS. 2A, 2B, 2C and 2D are cross-sectional views of a semiconductor device, illustrating the procedure for manufacturing the semiconductor device in the embodiment according to the present invention;

FIG. 3 is a cross-sectional view, schematically illustrating the semiconductor device in the embodiment of the present invention; and

FIGS. 4A, 4B, 4C and 4D are cross-sectional views, illustrating a procedure for manufacturing a semiconductor device in a comparative example.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Exemplary implementations according to the present invention will be described in detail as follows in reference to the annexed figures. In all figures, an identical numeral is assigned to an element commonly appeared in the figures, and the detailed description thereof will not be repeated.

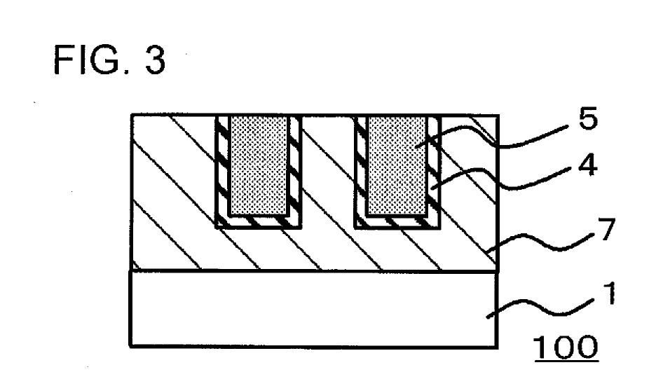

FIG. 3 shows a schematic cross-sectional view of a semiconductor device 100 of the present embodiment. FIG. 3 illustrates partially a multiple-layered interconnect of the semiconductor device 100 (semiconductor integrated circuit device).

As shown in FIG. 3, the semiconductor device 100 of the present embodiment includes a substrate (substrate 1), a microporous film 7 provided on the substrate 1 and a metallic film (barrier film 4 and copper interconnect 5) provided in the microporous film 7. In the present embodiment, a stress caused in the microporous film 7 in vicinity of the metallic film (barrier film 4 on copper interconnect 5) is a compressive stress. More specifically, since a stress acting toward a direction for expanding a volume in the inside of the microporous film 7, a counteraction for maintaining a constant volume also is generated in a portion of the microporous film 7 in contact with the external member such as the metallic film. Therefore, a compressive stress is generated in the microporous film from the barrier film 4. In other words, the stress in the portion of the microporous film 7 contacting with the barrier film 4 is a compressive stress. A substrate having, for example, an element such as a transistor or such element and an interconnect structure formed on a silicon substrate may be employed for the substrate 1.

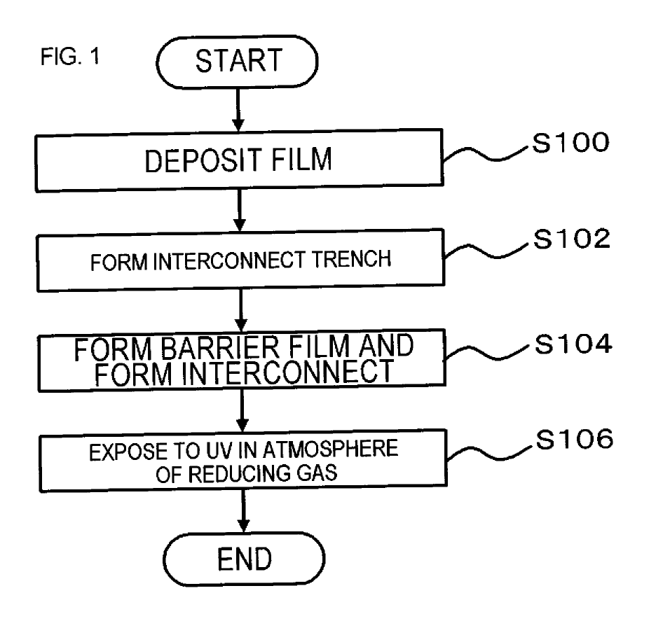

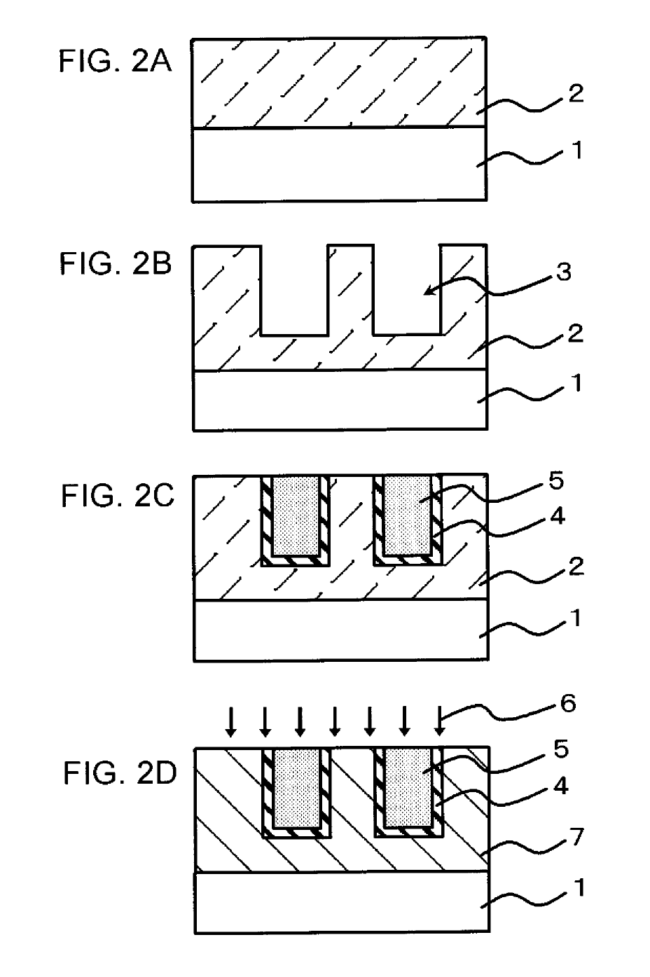

FIG. 1 shows an example of a flow chart of the procedure for manufacturing the semiconductor device 100 in the embodiment of the present invention. FIGS. 2A, 2B, 2C and 2D are cross-sectional views of a semiconductor device, illustrating the procedure for manufacturing the semiconductor device in the embodiment according to the present invention. The method for manufacturing the semiconductor device of the present embodiment includes: providing a film (organic silicon polymer film 2) containing a silane compound and a porogen on a substrate (substrate 1) having elements such as transistors (not shown) (S100); providing a hole (interconnect trench 3) in the organic silicon polymer film 2 using a selective etching process and providing a metallic film (barrier film 4 and copper interconnect 5) in the inside of the interconnect trench 3 (S102, S104); and conducting a radiation with ultraviolet 6 over the organic silicon polymer film 2 within an atmosphere of a reducing gas while the film is heated at a temperature of not lower than a boiling point or a decomposition temperature of the porogen to obtain a microporous film 7 (S106).

Respective steps will be described hereinafter.

### (S100)

The step 100 is an process operation for providing the organic silicon polymer film 2 (film containing silane compound and a porogen) on the substrate 1 (silicon substrate) having the elements such as transistors formed thereon (FIG. 2A).

First of all, in the method for manufacturing the semiconductor device 100, the elements such as transistors, resistors and the like and an interconnect layer that provides the elements are preliminarily formed on the surface of the substrate 1.

Then, a composition for forming a film containing a silane compound, a porogen and a surfactant solvent is prepared. The composition for forming a film is applied over the semiconductor substrate 1. In the present embodiment, siloxane oligomer is employed for the silane compound, and an alcohol and water are employed for the porogen. For example, a spin coats or the like is employed for the coating process.

Then, at least one treatment of a heating process, a radiation with electron beam, a radiation with ultraviolet, and an oxygen plasma-processing is conducted for the formed coating film. When the heat treatment process is conducted, a temperature lower than a boiling point or a decomposition temperature of the silane compound is preferably employed. Here, it is preferable to suitably select a condition for the heating treatment for the coating film to provide a reduced density the silane compound in the coating film. More specifically, the heating temperature may be, for example, equal to or higher than 200 degrees C. and equal to or lower than 400 degrees C. Such treatment is preferably conducted in a reduced pressure condition, or within an inactive gas atmosphere. Available atmosphere for the heating process may include atmospheric air, nitrogen atmosphere, argon atmosphere, vacuum, reduced pressure with controlled oxygen concentration and the like. The specific heating process is, for example, a process employing a hot plate. In the present embodiment, for example, the heating process up to 350 degrees C. is conducted within an inactive gas atmosphere.

In this way, the organic silicon polymer film 2 containing the porogen coexisting with the silane compound is formed on the semiconductor substrate 1.

Material for the silane compound according to the present embodiment is not particularly limited, provided that the silane compound is a compound having —Si—O— group. A cyclic silane or cyclosilane compound may be employed for the silane compound. Typical cyclosilane compound includes siloxane oligomer or the like. In this aspect, an organic group may be available for substitutional group on atomic Si. Typical organic group for atomic silicon may include, for example, a hydrogen, an alkyl group, an allyl group, an aryl group and the like.

The porogen according to the present embodiment may include a porogen such as acrylic polymer or the like, a porogen containing at least atomic carbon (C) or atomic hydrogen (H), or a porogen containing hydrocarbon and the like. Typical porogen containing hydrocarbon may include: (1) hydrocarbon represented by CxHy; and (2) oxygen-containing hydrocarbon represented by CxHyOz. In any of the cases of employing the hydrocarbon of (1) and hydrocarbon (2), the hydrocarbon, in which x is 1 to 12, is preferable, and the hydrocarbon may also have a molecular structure having a linear structure or a branched molecular structure. The porogen may also contain a compound, which preferably has, for example, a cyclic molecule structure, such as a benzene, or a cyclohexane.

The alcohol may include, for example, a methanol, an ethanol, a n-propanol, an isopropanol and the like. One of these alcohol may be employed alone, or a combination of these alcohols may alternatively be employed.

The surfactant may include, for example, a nonionic surfactant, an anionic surfactant, a cationic surfactant, an ampholytic surfactant and the like, and further, a fluorine-based surfactant, a silicone-based surfactant, a polyalkylene oxide-based surfactant, a poly(meta) acrylate-based surfactant and the like. One of these surfactants may be employed alone, or a combination of these alcohols may alternatively be employed.

### (S102, S104)

The step 102 and the step 104 are the operations for forming holes (interconnect trenches 3) in the organic silicon polymer film 2 using a selective etching process, and providing the metallic film (barrier film 4 and copper interconnect 5) in the inside of the interconnect trenches (FIG. 2B, 2C). In this operation, after a lithographic operation, in which a photo resist (hereinafter referred to as “resist”) is applied and an exposure development is conducted to pattern the resist, the organic silicon polymer film 2 is selectively dry-etched through a mask of the patterned resist to form the interconnect trenches 3.

After the interconnect trenches 3 are formed, the resist is removed. In a process for removing the resist, the temperature of the substrate is elevated to a temperature of 350 degrees C. and a radiation with ultraviolet is conducted, or the temperature of the substrate is elevated to a temperature of 350 degrees C. and a hydrogen radical exposure by high frequency excitation is conducted. In addition, exposure with oxygen radical or ozone gas in radical state by high frequency excitation at a substrate temperature of equal to or lower than 100 degrees C. is conducted. In such operation, a control of the elevating temperature, or a control of the ultraviolet energy, or a control of the partial pressure of oxygen gas, or a control of the partial pressure of ozone gas, or a combination thereof, may be employed, so that the process for removing the resist can be achieved without generating pores in the organic silicon polymer film 2.

After removing the resist, the barrier film 4 (first metallic film) having a thickness, which is about 1/10 of the depth of the interconnect trench 3, is formed on the surface of the microporous film 2 using a sputtering process. For example, tantalum (Ta) is employed for the barrier film 4.

Subsequently, a copper seed layer serving as an electrolytic plating feeding film is formed, and an electrolytic plating process is conducted to form a copper film (second metallic film). Thereafter, metal member formed outside of the interconnect trench 3 is removed using a chemical mechanical polishing (CMP) to form the copper interconnect 5 (FIG. 2C).

### (S106)

The step 106 is an operation for exposing the organic silicon polymer film 2 with ultraviolet radiation 6, while the film is heated to a temperature of equal to or higher than the boiling point or the decomposition temperature of the above-described porogen within a reducing gas atmosphere, to obtain the microporous film 7 (FIG. 2D).

In this operation, the organic silicon polymer film 2 is exposed to ultraviolet radiation of wave length of 200 nm to 500 nm within a reducing gas atmosphere at a temperature of equal to or higher than the boiling point or the decomposition temperature of the porogen. More specifically, the heating temperature may be, for example equal to or higher than 200 degrees C. and equal to or lower than 350 degrees C. Typical reducing gas may include one of hydrogen gas, hydrocarbon gas and organosilane gas, or a gaseous mixture thereof. In the present embodiment, for example, an exposure with the ultraviolet radiation 6 is carried out within an atmosphere of a reducing gas containing an organosilane gas at a temperature of equal to or lower than 350 degrees C. Moreover, the reducing gas is introduced before the exposure with the ultraviolet radiation 6. In addition, the flow rate of the reducing gas is stabilized during the exposure to the ultraviolet radiation 6.

The exposure to the ultraviolet radiation 6 allows achieving firm molecular backbone of the porous low-k film composed of Si—O—Si, and simultaneously accelerating an elimination of the porogen composed of C-Hn. Then, the microporous film 7 containing SiO₂ as a major constituent having holes formed in the portion of the organic silicon polymer film 2 where the porogen is removed therefrom is obtained.

When the microporous film 7 (interlayer insulating film) is formed in such process, first of all, in the step 100, the deposition is conducted with a material, which contains a molecular backbone-forming material as referred to as “matrix” and the porogen (pore formation material) composed of an organic polymer. Then, in the step 106, a thermally processing is conducted to decompose and remove the porogen. In this case, a thermal processing is conducted at a temperature, at which a decomposition of the porogen is caused and a decomposition of the molecular backbone-forming material is not caused, depending upon the type of the employed porogen. This allows obtaining the microporous film 7 having the holes formed in the portion where the porogen is removed.

In the present embodiment, the thermal processing using a radiation with the ultraviolet within a reducing gas atmosphere is carried out. Therefore, an internal stress for causing a volumetric expansion is generated in the inside of the microporous film 7, and a stress for compressing the microporous film 7 is generated in the portion of the microporous film 7 in contact with the barrier film 4. It is considered that the reason for generating the stress in the microporous film 7 is a combination of the effect of generating pores in the organic silicon polymer film 2 to cause a volumetric expansion therein and the effect of taking the reducing gas in a defect portion of the film base member to inhibit the shrinkage thereof.

In the present embodiment, a measurement of a compressive stress may be conducted as follows. In the method for measuring compressive stress, a value of a stress can be calculated on the basis of a warpage (namely, radius of curvature) of the semiconductor substrate 1 (wafer), which is obtained by an angle of reflection of entering laser beam in case of forming the microporous film 7 on the substrate 1. More specifically, first of all, a radiation with a laser beam is conducted for a sample for the measurement. Since a distortion (warpage) of the semiconductor substrate 1 is caused in the semiconductor substrate 1 having the microporous film 7 due to a stress from the microporous film 7, the laser beam entered on the substrate is reflected with a certain angle of reflection according to a level of the warpage. Scanning across the semiconductor substrate 1 is conducted for the radiations and measurements for angle of reflections with the above-described laser beam. The level of warpage of the entire semiconductor substrate 1 is obtained from the result. The same measurements are also carried out for the semiconductor substrate 1 without the microporous film 7, and then the difference in the level of warpage with and without the deposition of the microporous film 7 can be obtained. Such value is converted into a radius of a curvature of the sample after the deposition of the microporous film 7. The stress σ of the microporous film 7 is calculated with the following formula (Stoney's equation) by employing the obtained radius of curvature.

σ=(E·hₛ²)/[6(1−γ)r·h_{f}]

where:
E: Young's modulus of the substrate;
hₛ: thickness of the substrate;
γ: Poisson's ratio of the substrate;
r: radius of curvature; and
h_{f}: thickness of the microporous film 7.

As a result, the compressive stress of the microporous film 7 according to the present embodiment is not particularly limited, but may be, for example, equal to or higher than 20 MPa and equal to or lower than 100 MPa (within a range of from 20 MPa to 100 MPa). In particular, the compressive stress in the portion of the microporous film 7 provided with the copper interconnect 5 can be within the above-described range. The compressive stress within such range allows providing the semiconductor device 100 with improved reliability.

While porosity (volumetric porosity) in the microporous film 7 is not particularly limited, the porosity may be, for example, equal to or higher than 10% and equal to or lower than 60%. While the average pore diameter in the microporous film 7 is not particularly limited, the average pore diameter may be within a range of, for example, from 0.1 nm to 5 nm. In the present embodiment, the microporous film 7 having the volumetric porosity of 40% or higher is obtained. The use of such microporous film 7 allows reducing leakage current between adjacent interconnects and the like, so that the reliability of the signal propagation through the interconnect is improved.

The mean diameter of the pores can be obtained by analyzing results of small angle X-ray scattering analysis by utilizing analysis software “Nano-Solver”, commercially available from RIGAKU Corporation. Here, the principle of the software is described in, for example, Omote, Y., Ito, S., Kawamura, entitled “Small Angle X-Ray Scattering for Measuring Pore-Size Distribution in Porous Low-k Films,” Appl. Phys. Lett., Vol. 82, pp. 544-546 (2003). In addition, the porosity can be obtained by calculating the measurement results of the mean diameter of the pores, the specific dielectric constant, the refractive index and the density, or the like.

In addition, the available reducing gas in the present embodiment is not particularly limited, and for example, a gas, which is capable of being absorbed into the organic silicon polymer film 2 that is exposed to ultraviolet radiation 6 within a reducing gas atmosphere. For example, a gas containing a silicon (Si) or a hydrogen (H) in its molecular may be employed for the reducing gas. Typical reducing gas includes a hydrocarbon, a siloxane, an organosilane, a hydrogen gas, which may be employed alone, or a combination of which may be employed. The available siloxane is not particularly limited, and typically includes cyclosiloxanes such as a tetramethyl cyclotetrasiloxane having an organosilane group, an octamethylcyclotetrasiloxane and the like, and methylsiloxanes such as a dimethyl dihydroxy silyl cyclohexane, a dimethyl dimethoxy silane, a diethyl methoxy silane, a methyl triethylsilane and the like. In addition, typical organosilane includes an organosilane having an alkyl group, such as a trimethylsilane, a tetramethylsilane and the like, and organic silanamines such as a trimethylsilyl dimethylamine, a hexamethyldisilazane and the like. One of these organosilanes may be employed alone, or a combination of two or more organosilanes may be employed.

Hereafter, an interlayer insulating film may be further formed to provide a multi-layered interconnect structure. While only a cross-sectional view of the device including the single copper interconnect is illustrated in the annexed figures, a plurality of interconnects may additionally be provided in other regions. The semiconductor device of the present embodiment is obtained according to the above-described operations (FIG. 3).

Advantageous effects of the present embodiment will now be described. In the semiconductor device 100 according to the present embodiment, a compressive stress is generated in the microporous film 7 having the copper interconnect 5 formed therein (interlayer insulating film). More specifically, the volume of the microporous film 7 can be increased by generating pores of the porogen, while the volumetric shrinkage of the microporous film 7 due to the cross-linking reaction is inhibited.

Thus, since no tensile stress is exerted in the microporous film 7, a breakaway of the film due to a defect caused in the manufacturing process can be prevented, and a increased leakage current between interconnects due to a moisture absorption can be inhibited. As described above, the semiconductor device 100 with improved reliability can be achieved.

As described above, a deterioration of microporous film 7 due to the manufacturing process operations after the microporous film 7 having smaller dielectric constant is deposited as the interlayer insulating film can be prevented.

In addition, in the present embodiment, improved production yield in the manufacturing process is provided to reduce the manufacturing cost for the semiconductor device 100. In addition, since the microporous film 7 is the interlayer insulating film containing SiO₂ as the base material, smaller leakage between the interconnects achieves the semiconductor device 100 with improved performances, which is capable of operated at lower power consumption.

Since the organic components are maintained in the interlayer insulating film within the baking process and the process for forming the interconnect in the present embodiment, the damage caused by the plasma in the processes of the etching, the ashing and the barrier seed-spattering can be avoided. In addition, after the CMP process, the organic components are vaporized by the UV cure process in the reducing atmosphere. This allows the interlayer insulating film being composed of the porous SiO₂ film exhibiting higher porosity and having a compressive stress, so that improved production yield and quality of the multi-layer interconnect can be achieved.

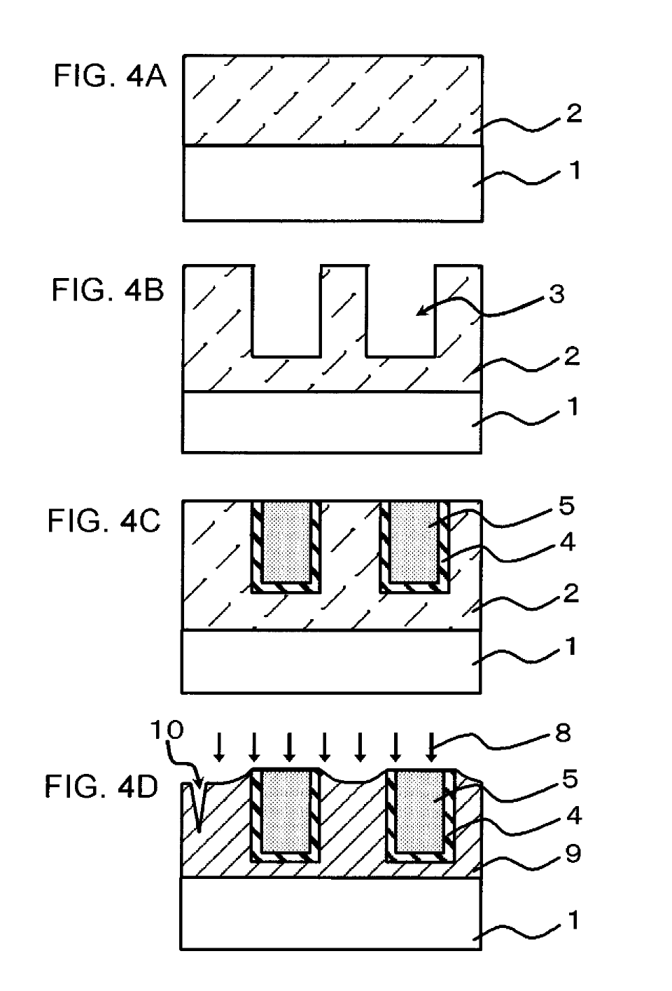

Next, the advantageous effects of the present embodiment will be further described in view of the comparison with a comparative example. In the method for manufacturing a porous interlayer insulating film in comparative example, as shown in FIGS. 4A to 4D, an organic silicon polymer film 2 containing a pore generating material dispersed therein is formed on a semiconductor substrate 1 having elements (not shown) formed thereon, and then interconnect trenches 3 are formed, and thereafter, a barrier film 4 and a copper interconnect 5 are formed by filling the trenches with materials. Hereafter, a pores treatment is conducted for the organic silicon polymer film 2 by utilizing ultraviolet radiation 8 and heat. As a result, pores are generated in the organic silicon polymer film 2 and simultaneously a shrinkage of the organic silicon polymer film 2 is caused to form the microporous film 9. The shrinking force exerting in the microporous film 9 results in the tensile stress exerting therein due to the adhesion of the microporous film 9 with the copper interconnect 5. More specifically, the internal stress for shrinkage acts over the microporous film 9, so that the microporous film 9 is subjected to a tensile stress from the copper interconnect, which is attached firmly to the microporous film 9. As a result, a crack 10 is generated in the microporous film 9.

Because of the lower crack resistance of the microporous film 9 that is subjected to the tensile stress in comparative example as described above, there is a problem of easily causing a breakaway of the film due to a crack generated in the manufacturing process. In addition, since the microporous film 9 absorbs water from the atmospheric air to cause a relaxation of stress, there is also a problem of an increased leakage current between interconnects by the moisture absorption.

On the contrary, in the present embodiment, the organic silicon polymer film 2 is exposed to ultraviolet radiation 6 within a reducing gas atmosphere at a temperature of equal to or higher than the boiling point or the decomposition temperature of the porogen. As a result, the internal stress for causing a volumetric expansion is generated over the microporous film 7 from the inside of the microporous film 7, so that the compressing stress is generated from the circumference. Thus, since no tensile stress is exerted over the microporous film 7 from the outside of the microporous film 7, a generation of a crack is inhibited, and a breakaway of the film due to a defect caused in the manufacturing process can be prevented, and a increased leakage current between interconnects due to a moisture absorption can be inhibited.

While the preferred embodiments of the present invention have been described above in reference to the annexed figures, it should be understood that the disclosures above are presented for the purpose of illustrating the present invention, and various modifications other than that described above are also available.

For example, the substrate, which is capable of being coated with a composition for forming a film of the present embodiment, may include semiconductor substrates, glass substrates, ceramics substrates, metallic substrates and the like. Typical coating process may include a spin coat process, a dipping process, a roller blade process and the like. Typical heating process may utilize a hot plate, an oven, a furnace or the like.

Typical atmosphere for the heating process may include atmospheric air, nitrogen atmosphere, argon atmosphere, vacuum, reduced pressure with controlled oxygen concentration and the like. In addition, in order to control cure rate of the above-described coated film, a stepwise heating may be employed, or atmospheres of nitrogen, air, oxygen, reduced pressure and the like may be selected, as required.

Materials for the microporous film 7 according to the present embodiment is not particularly limited, and materials having Si—O in its molecular as major constituent and having Si—O—Si bonds may be preferable. The microporous film 7 may be a film containing silicon (Si), oxygen (O) and carbon (C) as constituent elements, or a film containing Si, O, C and hydrogen (H) as constituent elements. In addition, for example, porous silica, or other films such as ultra low specific dielectric constant interlayer insulating films, porous interlayer films, films of porous silica, porous methyl silsesquioxane (porous MSQ), porous carbon containing silicon oxide film (porous SiOCH) and the like, may be employed for the microporous film 7. In addition, the structure of pores in the microporous film 7 is not particularly limited. The specific dielectric constant of the low dielectric constant film of the microporous film 7 may be, for example, equal to or lower than 3.0, and preferably equal to or lower than 2.0.

The composition for forming the film according to the present embodiment may further contains solvent. Available solvent is not particularly limited, and, for example, an organic solvent may be employed. Organic solvents such as, for example, an aliphatic hydrocarbon-based solvent, an aromatic hydrocarbon-based solvent, a ketone-based solvent, an ether-based solvent, an ester-based solvent, an amide-based solvent, a nitrogen-containing solvent, a sulfur-containing solvent and the like, may be employed. One of these solvents may be employed alone, or a combination of two or more organosilanes may be employed.

While tantalum (Ta) is exemplified as the barrier metal film in the present embodiment, the material for the barrier metal film is not limited thereto, and, when the interconnect is, for example, composed of metallic elements containing copper (Cu) as major constituent, a film of refractory metal materials such as a tantalum nitride (TaN), a titanium (Ti), a titanium nitride (TiN), a tungsten carbonitride (WCN) and a ruthenium (Ru), or nitrides thereof, or multiple-layered films composed of thereof, may be employed. In addition, the above-described metallic film may be employed for the barrier metal for the contact plug containing tungsten as major constituent.

While the exemplary implementation of the semiconductor device provided with the copper interconnect is described in the above-described embodiment, the interconnect may be primarily composed of a copper-containing metallic material. In addition, the process for forming the interconnect is not limited to the plating process, and for example, a chemical vapor deposition (CVD) process may be employed.

The metallic region (interconnect) of the present embodiment may be formed via a single damascene process or a dual damascene process.

It is apparent that the present invention is not limited to the above embodiment, and may be modified and changed without departing from the scope and spirit of the invention.

What is claimed is:

1. A method for manufacturing a semiconductor device, comprising:
providing a film containing a silane compound and a porogen over a substrate;
forming a hole in said film using a selective etching process and forming a metallic film in the inside of said hole: and
conducting a radiation with ultraviolet over said film within an atmosphere of a reducing gas while the film is heated at a temperature to obtain a microporous film, said temperature being not lower than a boiling point or a decomposition temperature of said porogen.

2. The method for manufacturing the semiconductor device as set forth in claim 1, wherein said reducing gas is a gas containing Si or H.

3. The method for manufacturing the semiconductor device as set forth in claim 1, wherein said reducing gas is a gas containing at least one selected from a group consisting of a hydrocarbon, a siloxane, an organosilane and a hydrogen.

4. The method for manufacturing the semiconductor device as set forth in claim 3, wherein said siloxane contains a cyclosiloxane or a methylsiloxane.

5. The method for manufacturing the semiconductor device as set forth in claim 4, wherein said cyclosiloxane contains a tetramethyl cyclotetrasiloxane having an organosilane group or an octamethylcyclotetrasiloxane.

6. The method for manufacturing the semiconductor device as set forth in claim 4, wherein said methylsiloxane contains at least one selected from a group consisting of a dimethyl dihydroxy silyl cyclohexane, a dimethyl dimethoxy silane, a diethyl methoxy silane and a methyl triethylsilane.

7. The method for manufacturing the semiconductor device as set forth in claim 3, wherein said organosilane contains at least one selected from a group consisting of a trimethylsilane, a tetramethylsilane, a trimethylsilyl dimethylamine and a hexamethyldisilazane.

8. The method for manufacturing the semiconductor device as set forth in claim 1, wherein said porogen contains C or H.

9. A semiconductor device, comprising:
a substrate;
a microporous film provided over said substrate;
a hole provided in said microporous film; and
a metallic film provided in the inside of said hole,
wherein a stress in said microporous film in vicinity of said metallic film is a compressive stress.

10. The semiconductor device as set forth in claim 9, wherein said microporous film is a film containing Si, O and C as constituent elements, or a film containing Si, O, C and H as constituent elements.

11. The semiconductor device as set forth in claim 9, wherein said microporous film contains Si and O.
